(19) United States
(12) Patent Application Publication
(10) Pub. No.: US 2026/0044283 A1
(43) Pub. Date: Feb. 12, 2026

(54) MEMORY DEVICES AND METHODS FOR OPERATING THE MEMORY DEVICES

(71) Applicant: Yangtze Memory Technologies Co., Ltd., Wuhan (CN)

(72) Inventors: Zhijiu ZHU, Wuhan (CN); Bo LI, Wuhan (CN); Zhenjia CHEN, Wuhan (CN); Dong HE, Wuhan (CN)

(21) Appl. No.: 18/889,258

(22) Filed: Sep. 18, 2024

Related U.S. Application Data
(63) Continuation of application No. PCT/CN2024/110898, filed on Aug. 9, 2024.

(51) Int. Cl. G06F 3/06

(52) U.S. Cl. CPC G06F 3/0659; G06F 3/0604; G06F 3/0634; G06F 3/0679

(57) ABSTRACT

Systems, devices, and methods for managing operation setting information in memory devices are provided. In one aspect, a memory device includes a memory cell array comprising memory cells, and a peripheral circuit coupled to the memory cell array. The peripheral circuit is configured to in response to receiving a first operation command, perform a first operation corresponding to a first type of operation on the memory cell array according to first operation setting information. In response to receiving a second operation command, the peripheral circuit is configured to obtain second operation setting information from the memory cell array and perform a second operation corresponding to a second type of operation on the memory cell array according to the second operation setting information, wherein the second type of operation is different from the first type of operation.

### CROSS-REFERENCE TO RELATED APPLICATIONS

This application is a continuation of International Application No. PCT/CN2024/110898, filed on Aug. 9, 2024, the disclosure of which is hereby incorporated by reference in its entirety.

### TECHNICAL FIELD

The present disclosure relates to memory devices and memory systems, and in particular, to managing operation setting information in memory devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems and techniques for managing operation setting information in memory devices.

One aspect of the present disclosure features a memory device including a memory cell array comprising memory cells and a peripheral circuit coupled to the memory cell array and configured to: in response to receiving a first operation command, perform a first operation corresponding to a first type of operation on the memory cell array according to first operation setting information; and in response to receiving a second operation command, obtain second operation setting information from the memory cell array and perform a second operation corresponding to a second type of operation on the memory cell array according to the second operation setting information, wherein the second type of operation is different from the first type of operation.

In some implementations, the peripheral circuit comprises a cache memory configured to store one of the first operation setting information or the second operation setting information.

In some implementations, only one of the first operation setting information or the second operation setting information is stored in the cache memory at a time point.

In some implementations, a memory area occupied by the first operation setting information has a first address range in the cache memory, a memory area occupied by the second operation setting information has a second address range in the cache memory, and the first address range and the second address range share at least one common address.

In some implementations, the cache memory is configured to be preloaded with the first operation setting information, and wherein the cache memory is configured to store the second operation setting information obtained from the memory cell array.

In some implementations, each of the first operation and the second operation comprises a write operation.

In some implementations, the peripheral circuit is configured to: operate a first memory cell according to the first type of operation, the first memory cell is configured to store a first number of bits; and operate a second memory cell according to the second type of operation, the second memory cell is configured to store a second number of bits, and wherein the first number of bits is different from the second number of bits.

In some implementations, the first type of operation is quad-level cell (QLC) operation, and wherein the second type of operation is triple-level cell (TLC) operation.

In some implementations, the peripheral circuit is configured to: perform the first operation by applying a first voltage to a first selected word line; and perform the second operation by applying a second voltage to a second selected word line, wherein the first voltage and the second voltage are different in at least one of amplitude or pulse width.

In some implementations, the memory cell array comprises a configure block, and wherein the first operation setting information and the second operation setting information are stored in different areas of the configure block, and wherein the peripheral circuit is configured to obtain the second operation setting information from the configure block in the memory cell array.

In some implementations, the memory cell array comprises: a first configure block configured to store the first operation setting information, and a second configure block configured to store the second operation setting information, wherein the peripheral circuit is configured to obtain the second operation setting information from the second configure block in the memory cell array.

In some implementations, the peripheral circuit is configured to: perform first operations corresponding to the first type of operation on memory cells in a same block; and perform second operations corresponding to the second type of operation on memory cells in another same block.

In some implementations, the memory device is a NAND flash memory device.

In some implementations, each of the second operation setting information and the first operation setting information respectively comprises at least one of: voltage control information; timing control information; or process control information.

Another aspect of the present disclosure features a memory device comprising: a memory cell array comprising memory cells; and a peripheral circuit coupled to the memory cell array and configured to: receive an operation command corresponding to a current type of operation; determine whether the current type of operation is same as a previous type of operation; and if the current type of operation is different from the previous type of operation, obtain current operation setting information for the current type of operation from the memory cell array and perform a first operation corresponding to the operation command on the memory cell array according to the current type of operation and the current operation setting information.

In some implementations, the peripheral circuit is configured to: if the current type of operation is same as the previous type of operation, perform a second operation corresponding to the operation command on the memory cell array according to the previous type of operation and previous operation setting information for the previous type of operation.

In some implementations, the peripheral circuit comprises a cache memory, and wherein the peripheral circuit is configured to: preload the cache memory with default operation setting information; and set a type of operation corresponding to the default operation setting information as a default type of operation.

In some implementations, the default type of operation is quad-level cell (QLC) operation or triple-level cell (TLC) operation.

In some implementations, the memory cell array comprises a configure block, and wherein obtaining the current operation setting information from the memory cell array comprises: obtaining the current operation setting information from the configure block; and replacing previous operation setting information in the cache memory with the current operation setting information.

In some implementations, the previous operation setting information and the current operation setting information are stored in different areas of the configure block at a time point.

In some implementations, the peripheral circuit comprises a register, and wherein the peripheral circuit is configured to: store the previous type of operation in the register, wherein determining whether the current type of operation is same as the previous type of operation comprises comparing the current type of operation with the previous type of operation stored in the register.

In some implementations, the peripheral circuit is configured to: after performing the first operation, set the current type of operation in the register as a new previous type of operation.

A further aspect of the present disclosure features a method including receiving, by a peripheral circuit of a memory device, an operation command corresponding to a current type of operation, wherein the memory device comprises a memory cell array coupled to the peripheral circuit; determining, by the peripheral circuit, whether the current type of operation is same as a previous type of operation; and if the current type of operation is different from the previous type of operation, obtaining current operation setting information for the current type of operation from the memory cell array and performing a first operation corresponding to the operation command on the memory cell array according to the current type of operation and the current operation setting information.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a block diagram of an example system having a memory device, according to one or more aspects of the present disclosure.

FIG. 1B illustrates example interactions between a memory controller and a memory device, according to one or more aspects of the present disclosure.

FIGS. 2A-2B illustrate example storage products, according to one or more aspects of the present disclosure.

FIG. 3 illustrates a schematic diagram of an example memory device including peripheral circuits, according to one or more aspects of the present disclosure.

FIG. 4 illustrates an example peripheral circuit, according to one or more aspects of the present disclosure.

FIGS. 5A-5B illustrate block diagrams of a portion of a memory device for managing operation setting information in the memory device, according to one or more aspects of the present disclosure.

FIG. 6 illustrates example clock cycle diagrams for an example QLC command and an example TLC command, according to one or more aspects of the present disclosure.

FIG. 7 illustrates example voltage diagrams for sensing a configure block based on an operation command, according to one or more aspects of the present disclosure.

FIG. 8 illustrates example clock cycle diagrams for storing operation setting information in a cache memory, according to one or more aspects of the present disclosure.

FIG. 9 illustrates example voltage diagrams for performing a write operation on a memory cell array according to operation setting information, according to one or more aspects of the present disclosure.

FIG. 10 illustrates a flowchart of an example process for managing operation setting information in a memory device, according to one or more aspects of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

Implementations of the present disclosure provide methods, devices, systems and techniques for managing operation setting information in memory devices. For example, an example memory device includes a memory cell array of memory cells and a peripheral circuit coupled to the memory cell array. The peripheral circuit is configured to: in response to receiving a first operation command, perform a first operation corresponding to a first type of operation on the memory cell array according to first operation setting information; and in response to receiving a second operation command, obtain second operation setting information from the memory cell array and perform a second operation corresponding to a second type of operation on the memory cell array according to the second operation setting information, wherein the second type of operation is different from the first type of operation.

Implementations of the present disclosure can provide one or more of the following technical advantages and/or benefits. For example, in some cases, the operation setting information for all types of operations can be stored in one or more configuration blocks of a memory device. As, at any given time, not all types of operation setting information are stored in the cache memory of the memory device, the techniques enable to load, the relevant operation setting information into the cache memory depending on the type of operation command, replacing at least a part of the operation setting information previously stored in the cache memory. Compared to storing the operation setting information for all types of operation in the cache memory simultaneously, the techniques can reduce the required cache memory space, thereby lowering the cost of the memory device.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. Additionally or alternatively, the techniques can be applied to various types of devices and systems, such as secure digital (SD) cards, embedded multimedia cards (eMMC), or solid-state drives (SSDs), embedded systems, among others.

In some cases, the techniques can be applied to a semiconductor device having two or more memory types, such as two or more of the single-level cell (SLC), multi-level cell (MLC), triple-level cell (TLC), quad-level cell (QLC), and penta-level cell (PLC) memory types. For example, the techniques can be applied to a semiconductor device having a memory block programmed using the TLC memory type and another memory block programmed using the QLC memory type. An example application of the techniques is on the fly (OTF) TLC in QLC NAND flash memory devices. In some cases, using TLC to store system cold data can enhance system performance while maintaining high storage density. The OTF requirement is to switch between QLC and TLC operations without powering down the memory device. Thus, such memory device needs to be compatible with both QLC and TLC.

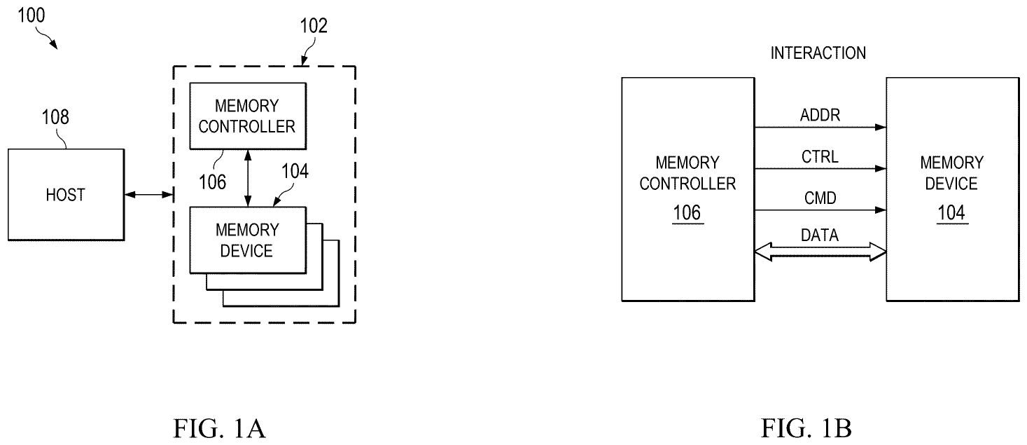

FIG. 1A illustrates a block diagram of an example system 100 having a memory device, according to one or more aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1A, the system 100 can include a host 108 and a memory system 102 having one or more memory devices 104 and a memory controller 106. The host 108 can include one or more processors of an electronic device. The processor can be a central processing unit (CPU), or a system-on-chip (SoC), such as an application processor (AP). The host 108 can be configured to send or receive data and commands to or from the memory systems 102.

The memory device 104 can be any memory device disclosed in the present disclosure, such as a NAND flash memory device. It is noted that the NAND flash is only one example of memory device for illustrative purposes. It can include any suitable solid-state, non-volatile memory, e.g., NOR flash, Ferroelectric RAM (FeRAM), Phase-change memory (PCM), Magne-to-resistive random-access memory (MRAM), Spin-transfer torque magnetic random-access memory (STT-RAM), or Resistive random-access memory (RRAM), etc. In some implementations, memory device 104 includes a three-dimensional (3D) NAND flash memory device.

The memory controller 106 can be implemented by microprocessors, microcontrollers (a.k. a. microcontroller units (MCUs)), digital signal processors (DSPs), application-specific integrated circuits (ASICs), field-programmable gate arrays (FPGAs), programmable logic devices (PLDs), state machines, gated logic, discrete hardware circuits, and other suitable hardware, firmware, and/or software configured to perform the various functions described below in detail.

The memory controller 106 is coupled to the memory device 104 and to the host 108, and is configured to control the memory device 104, according to some implementations. The memory controller 106 can manage the data stored in the memory device 104 and can communicate with the host 108. In some implementations, the memory controller 106 is designed for operating in a low duty-cycle environment, such as secure digital (SD) cards, compact flash (CF) cards, universal serial bus (USB) flash drives, or other media for use in electronic devices, such as personal computers, digital cameras, mobile phones, etc. In some implementations, memory controller 106 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. The memory controller 106 can be configured to control operations of the memory device 104, such as read, erase, and program operations. The memory controller 106 can also be configured to manage various functions with respect to the data stored or to be stored in the memory device 104 including, but not limited to bad-block management, garbage collection, logical-to-physical address conversion, logical-to-physical mapping management, wear leveling, etc. In some implementations, the memory controller 106 is further configured to process error correction codes (ECCs) with respect to the data read from or written to the memory device 104. Any other suitable functions can be performed by the memory controller 106 as well, for example, formatting the memory device 104.

FIG. 1B illustrates example interactions between the memory controller 106 and the memory device 104, according to one or more aspects of the present disclosure. In some cases, the memory controller can transmit at least one of address information, control information, command(s), and data associated with the command(s) to the memory device 104. The memory device 104 can perform operation(s) associated with the command(s) and/or return data associated with the operation(s) to the memory controller 106. In one example, when performing a write operation, the memory controller 106 transmits a write command, data to be written, address information for the data to be stored in the memory device 104 to the memory device 104. The memory device 104 can perform the write operation according to the write command to program the data in the designated addresses. In another example, when performing a read operation, the memory controller 106 transmits a read command and address information for data to be read from the memory device 104. The memory device 104 can perform the read operation according to the read command to read the data from the designated addresses in the memory device 104. The memory device 104 can then transmit the read data to the memory controller 106.

The memory controller 106 can communicate with an external device (e.g., the host 108) according to a particular communication protocol. For example, the memory controller 106 can communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc. The memory controller 106 is configured to receive and transmit a command to and from the host 108, and execute or perform multiple functions and operations provided in the present disclosure, which will be described later.

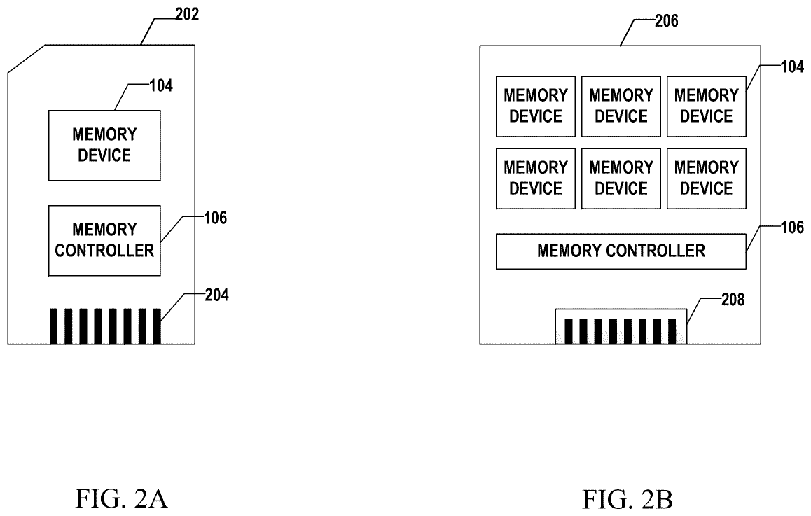

The memory controller 106 and the one or more memory devices 104 can be integrated into various types of storage devices. For example, the memory controller 106 and the one or more memory devices 104 can be packaged in a universal flash storage (UFS) package or an eMMC package. In one example as shown in FIG. 2A, the memory controller 106 and a single memory device 104 can be integrated into a memory card 202. The memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 can further include a memory card connector 204 coupling the memory card 202 with a host (e.g., host 108 in FIG. 1A). In another example as shown in FIG. 2B, the memory controller 106 and multiple memory devices 104 can be integrated into an SSD 206. The SSD 206 can further include an SSD connector 208 that couples the SSD 206 with a host (e.g., host 108 in FIG. 1A). In some implementations, the storage capacity and/or the operation speed of the SSD 206 is greater than those of the memory card 202.

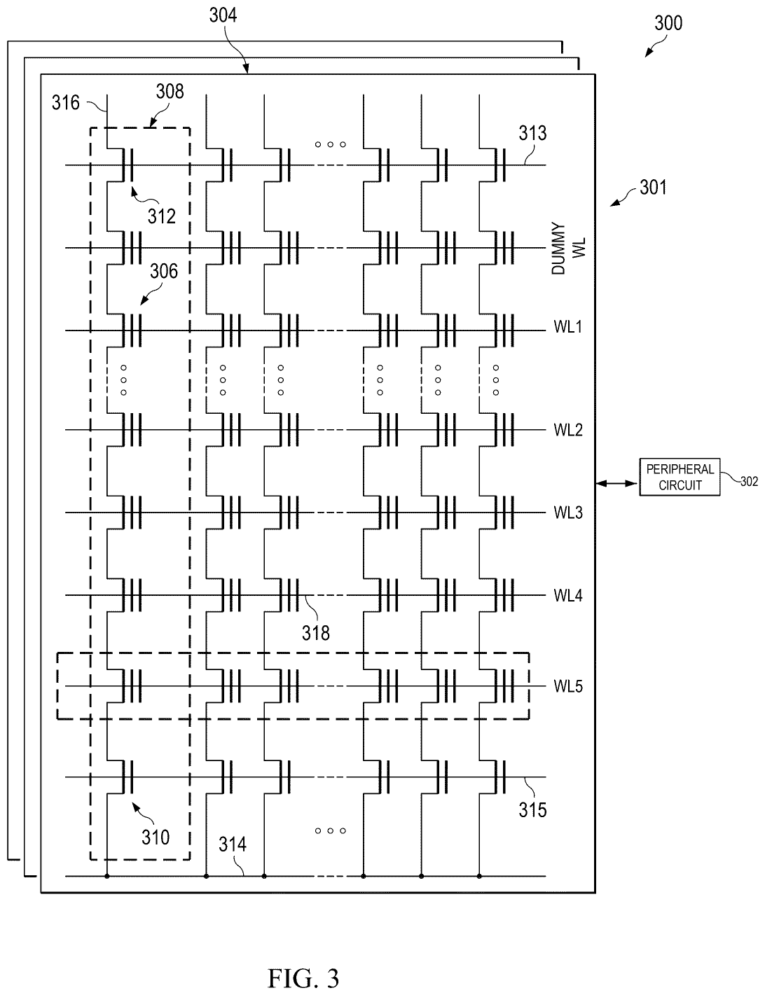

FIG. 3 illustrates a schematic diagram of an example memory device 300 including peripheral circuits, according to one or more aspects of the present disclosure. The memory device 300 can include a memory cell array 301 and peripheral circuits 302 coupled to the memory cell array 301. The memory cell array 301 can be a NAND flash memory cell array in which memory cells 306 are provided in the form of an array of NAND memory strings 308 each extending vertically above a substrate (not shown in FIG. 3). In some implementations, each NAND memory string 308 includes a plurality of memory cells 306 coupled in series and stacked vertically. Each memory cell 306 can hold a continuous, analog value, such as an electrical voltage or charge that depends on the number of electrons trapped within a storage layer of the memory cell 306. The logic state (i.e., data) of each memory cell 306 in a memory block 304 can be determined based on the threshold voltage Vth of the memory cell 306. Each memory cell 306 can be a floating gate type memory cell including a floating-gate transistor, or a charge trap type memory cell including a charge-trap transistor.

In some implementations, each memory cell 306 is a single-level cell (SLC) with two possible memory states that can store one bit of data. For example, the first memory state “0” can correspond to a first range of voltages, and the second memory state “1” can correspond to a second range of voltages. In some implementations, each memory cell 306 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 3, each NAND memory string 308 can include a source select gate (SSG) 310 at its source end and a drain select gate (DSG) 312 at its drain end. The SSG 310 and the DSG 312 can be configured to activate selected NAND memory strings 308 (columns of the array) during read and program operations. In some implementations, the sources of NAND memory strings 308 in the same memory block 304 are coupled through a same source line (SL) 314, e.g., a common SL. In other words, NAND memory strings 308 in the same memory block 304 have an array common source (ACS), according to some implementations. The DSG 312 of each NAND memory string 308 is coupled to a respective bit line 316 from which data can be read or written via an output bus (not shown), according to some implementations. In some implementations, each NAND memory string 308 is configured to be selected or deselected by applying a select voltage (e.g., above the threshold voltage of the transistor having the DSG 312) or a deselect voltage (e.g., 0 V) to the respective DSG 312 through one or more DSG lines 313, and/or by applying a select voltage (e.g., above the threshold voltage of the transistor having the SSG 310) or a deselect voltage (e.g., 0 V) to the respective SSG 310 through one or more SSG lines 315.

As shown in FIG. 3, NAND memory strings 308 can be organized into multiple memory blocks 304, each of which can have a common SL 314 coupled to the ACS. In some implementations, each memory block 304 can serve as a basic data unit for erase operations, such that memory cells 306 on the same memory block 304 are erased at the same time. To erase memory cells 306 in a selected memory block 304, the SL 314 coupled to the selected memory block 304 and unselected memory blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of memory blocks or fractions of a memory block.

The memory cells 306 of adjacent NAND memory strings 308 can be coupled through word lines 318. The word line 318 can select which row of memory cells 306 is affected by read and program operations. Each word line 318 can include a gate line coupled to a plurality of control gates (gate electrodes) of a plurality of memory cells 306. Example word lines shown in FIG. 3 are between one or more DSG lines 313 and one or more SSG lines 315.

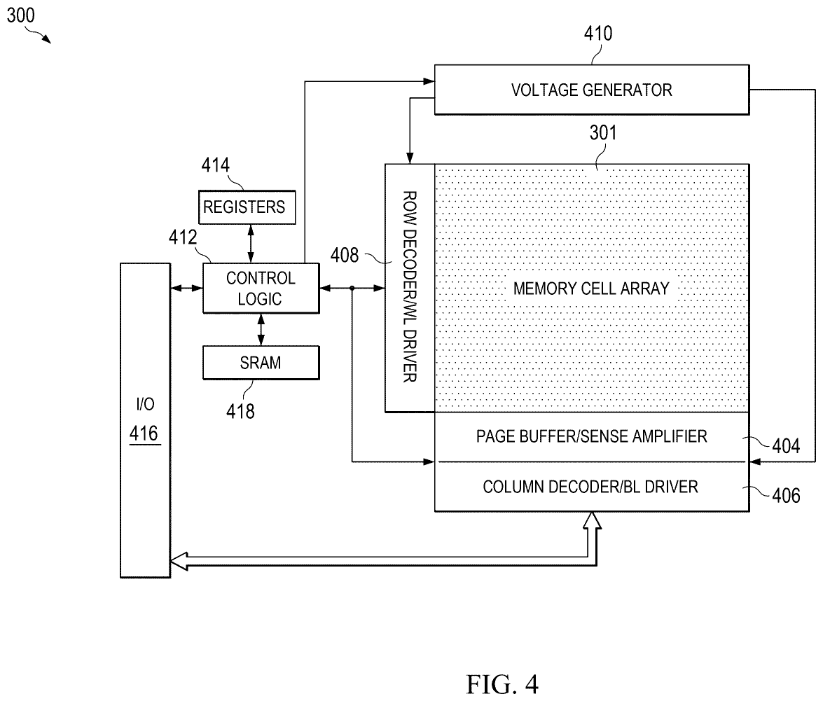

FIG. 4 illustrates an example peripheral circuit 302, according to one or more aspects of the present disclosure. The peripheral circuits 302 can be coupled to the memory cell array 301 through bit lines 316, word lines 318, SLs 314, SSG lines 315, and DSG lines 313. The peripheral circuits 302 can include any suitable analog, digital, and mixed-signal circuits for facilitating the operations of the memory cell array 301 by applying and sensing voltage signals and/or current signals to and from each target memory cell 306 through bit lines 316, word lines 318, SLs 314, SSG lines 315, and DSG lines 313. The peripheral circuits 302 can include various types of peripheral circuits formed using metal-oxide-semiconductor (MOS) technologies. The example peripheral circuits 302 include a page buffer/sense amplifier 404, a column decoder/bit line driver 406, a row decoder/word line driver 408, a voltage generator 410, control logic 412, registers 414, an input/output (I/O) interface 416, a static random-access memory (SRAM), and a data bus. In some examples, additional peripheral circuits not shown in FIG. 4 may be included as well.

The page buffer/sense amplifier 404 can be configured to read and program (write) data from and to memory cell array 301 according to the control signals from control logic 412. In another example, the page buffer/sense amplifier 404 may perform program verify operations to ensure that the data have been properly programmed into memory cells 306 coupled to selected word lines 318. In still another example, the page buffer/sense amplifier 404 may also sense the low power signals from the bit line 316 that represents a data bit stored in memory cell 306, and amplify the small voltage swing to recognizable logic levels in a read operation. The column decoder/bit line driver 406 can be configured to be controlled by the control logic 412 and select one or more NAND memory strings 308 by applying bit line voltages generated from the voltage generator 410.

The row decoder/word line driver 408 can be configured to be controlled by the control logic 412 and select/deselect memory blocks 304 of the memory cell array 301 and select/deselect word lines 318 of the memory block 304. The row decoder/word line driver 408 can be further configured to drive word lines 318 using word line voltages generated from the voltage generator 410. In some implementations, the row decoder/word line driver 408 can also select/deselect and drive SSG lines 415 and DSG lines 413. As described below in detail, the row decoder/word line driver 408 is configured to apply a program voltage to selected word line 318 in a program operation on memory cell 306 coupled to selected word line 318.

The voltage generator 410 can be configured to be controlled by the control logic 412 and generate the word line voltages (e.g., read voltage, program voltage, pass voltage, local voltage, verify voltage, etc.), bit line voltages, and source line voltages to be supplied to the memory cell array 301.

The control logic 412 can be coupled to each peripheral circuit described above and configured to control operations of each peripheral circuit. The registers 414 can be coupled to the control logic 412 and include status registers, command registers, and address registers for storing status information, command operation codes (OP codes), and command addresses for controlling the operations of each peripheral circuit.

The I/O interface 416 can be coupled to the control logic 412 and act as a control buffer to buffer and relay control commands received from a memory controller to the control logic 412 and status information received from the control logic 412 to the memory controller. The I/O interface 416 can also be coupled to the column decoder/bit line driver 406 via a data bus, and act as a data input/output (I/O) interface and a data buffer to buffer and relay data to and from the memory cell array 301.

The SRAM 418 can be coupled to the control logic 412 and be configured to store operation setting information. In some implementations, the peripheral circuit (e.g., the control logic 412) can be configured to obtain the operation setting information from memory cell array 301 (e.g., from a configure block in the memory cell array 301) and store the operation setting information in the SRAM 418.

The operation setting information can vary based on the types of operation. In some cases, the types of operation can include, but are not limited to, SLC operation, MLC operation, TLC operation, QLC operation, and PLC operation. The operation can be, for example, a write operation or a read operation. So, for example, the operation setting information of TLC operation can be different from the operation setting information of QLC operation. The operation setting information for a write operation can differ from that for a read operation, even within the same type of operation.

In some cases, the operation setting information includes at least one of voltage control information, timing control information, or process control information. Taking the QLC writing operation as an example, the voltage control information can include at least one of word line bias source, selected word line voltage, unselected word line voltage, special word line voltage, voltages in the page buffer controlling the bit lines, or other suitable voltage control information. The timing control information can include timing control information associated with controlling the word lines and/or bit lines, such as width pulses of programming, verification sensing time, or other suitable timing control information. The process control information can include the process control information associated with the start of each state verification, the start of unselect string boosting enhancement (USBE), or other suitable process control information.

In some implementations, the operation setting information of a type of operation can include a plurality of parameters and their corresponding parameter vales. For example, the operation setting information of a type of operation can include one or more voltage control parameters, one or more timing control parameters, and/or one or more process control parameters, and their corresponding parameter values. In some cases, the difference in operation setting information between two types of operation can be due to at least one different parameter, different parameter values for at least one parameter, or both.

According to the operation setting information in the SRAM 418, the peripheral circuit can be configured to perform an operation corresponding to a type of operation on the memory cell array. For example, the peripheral circuit can perform a write or a read operation corresponding to a type of operation (e.g., SLC operation, MLC operation, TLC operation, QLC operation, or PLC operation) on the memory cell array using at least one of voltage control information, timing control information, or process control information in the operation setting information corresponding to the type of operation.

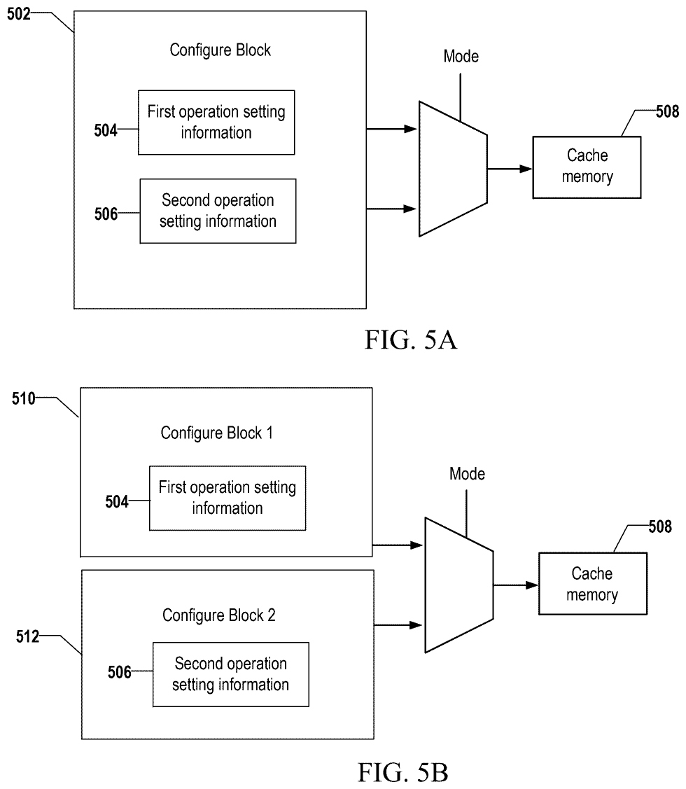

FIGS. 5A-5B illustrate block diagrams of a portion of a memory device for managing operation setting information in the memory device, according to one or more aspects of the present disclosure. In some cases, the first operation setting information 504 and the second operation setting information 506 are stored in the same configure block. For example, as illustrated in FIG. 5A, the first operation setting information 504 and the second operation setting information 506 are stored in different areas of the configure block 502.

Alternatively, the first operation setting information 504 and the second operation setting information 506 are stored in different configure blocks. For example, as illustrated in FIG. 5B, the first operation setting information 504 is stored in the configure block 510 and the second operation setting information 506 is stored in the configure block 512. Each of the configure block 502, configure block 510, and configure block 512 can be in a memory cell array (e.g., the memory cell array 301).

In some cases, the memory device can include one or more backup configure blocks. If a working configure block becomes faulty, a backup configure block can replace the working configure block for storing operation setting information.

In some cases, a cache memory 508 is structurally and/or functionally similar to the SRAM 418 of FIG. 4. In some implementations, the cache memory 508 is configured to store one of the first operation setting information 504 or the second operation setting information 506. In other words, only one of the first operation setting information 504 or the second operation setting information 506 is stored in the cache memory 508 at any time point. Therefore, the size of the cache memory 508 only needs to be large enough to store the greater of the first operation setting information 504 or the second operation setting information 506.

Therefore, a memory area occupied by the first operation setting information 504 in the cache memory 508 and a memory area occupied by the first operation setting information 504 in the cache memory 508 can overlap. For example, in some implementations, when the first operation setting information 504 is stored in the cache memory 508, a memory area occupied by the first operation setting information 504 has a first address range in the cache memory 508. When the second operation setting information 506 is stored in the cache memory 508, a memory area occupied by the second operation setting information 506 has a second address range in the cache memory 508. The first address range and the second address range share at least one common address.

In some examples, in response to receiving a first operation command, the peripheral circuit (e.g., the control logic 412) can obtain the first operation setting information 504 from the configure block (e.g., the configure block 502 or the configure block 510) in the memory cell array. The peripheral circuit can then load the first operation setting information 504 in the cache memory 508. The peripheral circuit can then perform a first operation corresponding to a first type of operation on the memory cell array according to the first operation setting information 504 stored in the cache memory 508. Examples of the type of operation can be those discussed with respect to FIG. 4, and are omitted here for brevity.

Alternatively or additionally, the cache memory 508 can be preloaded with the first operation setting information 504. Therefore, in response to receiving the first operation command, the peripheral circuit can perform the first operation corresponding to the first type of operation without obtaining the first operation setting information 504 from the configure block.

Similarly, in some examples, in response to receiving a second operation command, the peripheral circuit (e.g., the control logic 412) can obtain the second operation setting information 506 from the configure block (e.g., the configure block 502 or the configure block 512) in the memory cell array. The peripheral circuit can then store the second operation setting information 506 in the cache memory 508. In some cases, the cache memory 508 stores other operation setting information, such as the first operation setting information 504, before storing the second operation setting information 506. In such case, the other operation setting information stored in the cache memory 508 can be partially or completely overwritten when the second operation setting information 506 is stored in the cache memory 508. The peripheral circuit can then perform a second operation corresponding to a second type of operation on the memory cell array according to second operation setting information 506 stored in the cache memory 508.

Alternatively or additionally, the cache memory 508 can be preloaded with the second operation setting information 506. Therefore, in response to receiving the second operation command, the peripheral circuit can perform the second operation corresponding to the second type of operation without obtaining the second operation setting information 506 from the configure block.

In some cases, the second type of operation is different from the first type of operation. For example, the first type of operation is QLC operation and the second type of operation is TLC operation. Accordingly, a memory cell operated (e.g., read or written) based on the first type of operation can be different from a memory cell operated based on the second type of operation. For example, a first memory cell operated according to the first type of operation is configured to store a first number of bits. A second memory cell operated cell according to the second type of operation is configured to store a second number of bits. The first number of bits is different from the second number of bits. As an example, assume that the first type of operation is QLC operation and the second type of operation is TLC operation. The memory cell operated according to the QLC operation is configured to store 4 bits, whereas the memory cell operated according to the TLC operation is configured to store 3 bits.

In some implementations, the peripheral circuit performs operations corresponding to the same type of operation on memory cells in the same block (e.g., the memory block 304). In some cases, a block includes a plurality of pages, and all pages in the block are performed the same type of operation. For example, assuming that the peripheral circuit is configured to perform QLC write operations on a block, the peripheral circuit can perform a QLC write operation on each page within that block.

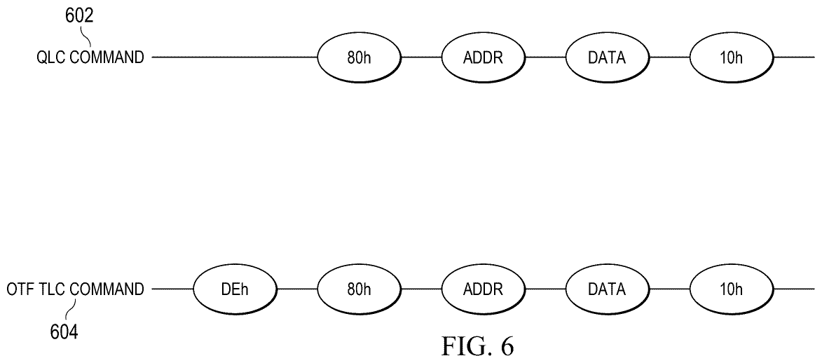

FIGS. 6-9 illustrate example clock cycle diagrams and voltage diagrams for operation commands, according to one or more aspects of the present disclosure. FIG. 6 illustrates example clock cycle diagrams for an example QLC command 602 and an example TLC command 604. As illustrated in FIG. 6, “DEh” can indicate that the operation command is a TLC command. Each of the QLC command 602 and the TLC command 604 includes address(es) and data associated with the operation command. The address(es) can include, for example, the address of the block or the address of the page to be operated by the operation command. The data can indicate, for example, the data to be written to or to be read from the block or page associated with the address(es).

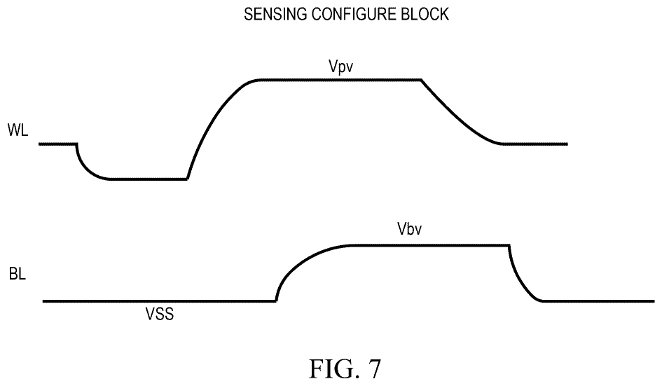

In response to receiving an operation command, the peripheral circuit can sense the configure block to obtain operation setting information corresponding to the operation command. FIG. 7 illustrates example voltage diagrams for sensing the configure block based on an operation command. As illustrated in FIG. 7, when sensing the configure block, the peripheral circuit can apply a voltage Vₚᵥ to a selected word line and apply a bit line voltage V_{bv} to a selected bit line. The bit line voltage V_{bv} is higher than a standby voltage VSS for the selected bit line.

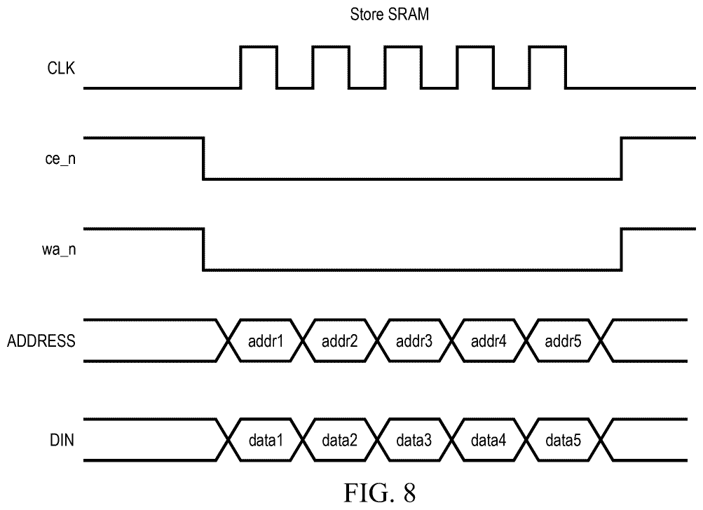

The peripheral circuit can store the operation setting information in the cache memory, such as a SRAM. FIG. 8 illustrates example clock cycle diagrams for storing the operation setting information in a cache memory. As illustrated by FIG. 8, storing the operation setting information in the cache memory can involve a plurality of clock cycles (e.g., “CLK” shown in FIG. 8). Each clock cycle can be associated with an address (e.g., the address to store a piece of operation setting information) and data (e.g., “DIN” shown in FIG. 8) corresponding to the address (e.g., the piece of operation setting information to be stored in the address). In some cases, the addresses and data corresponding to the addresses can vary by the type of operation. For example, the first operation setting information corresponding to the first type of operation can be stored in the cache memory at a first plurality of addresses, whereas the second operation setting information corresponding to the second type of operation in the cache memory can be stored at a second plurality of addresses. The first plurality of addresses and the second plurality of addresses can have at least one different address. As illustrated in FIG. 8, the “ce_n” shows the enabling signal associated with the plurality of clock cycles. The “wa_n” illustrates the writing signal associated with the plurality of clock cycles.

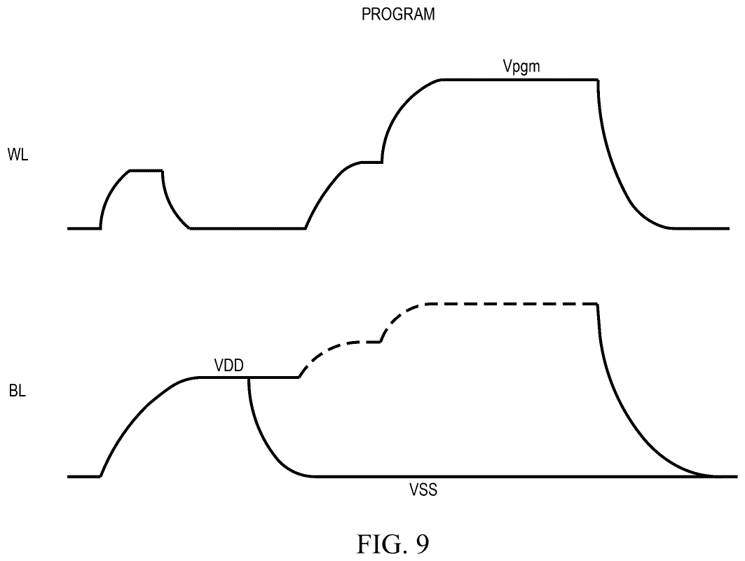

The peripheral circuit can perform an operation (e.g., write or read) corresponding to a type of operation on the memory cell array according to the operation setting information stored in the cache memory. FIG. 9 illustrates example voltage diagrams for performing a write operation on the memory cell array according to the operation setting information. As illustrated in FIG. 9, when performing the write operation on the memory cell array, the peripheral circuit can apply a voltage V_{pgm} to a selected word line and apply a voltage VDD or VSS to a selected bit line. In some cases, the voltage applied to a selected word line can vary by the type of operation. For example, when performing a first type of operation, the peripheral circuit can apply a first voltage to a first selected word line. When performing a second type of operation, the peripheral circuit can apply a second voltage to a second selected word line. The first voltage and the second voltage can be different in at least one of amplitude or pulse width.

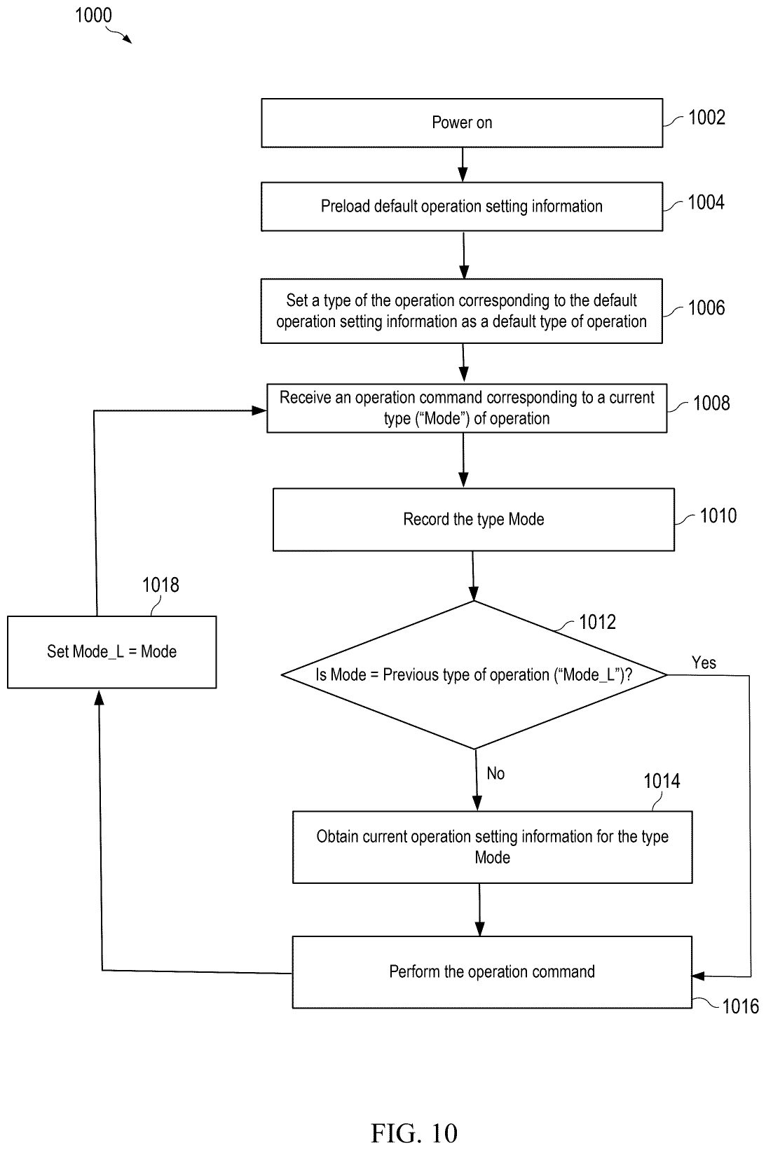

FIG. 10 illustrates a flowchart of an example process 1000 for managing operation setting information in memory devices, according to one or more aspects of the present disclosure. The process 1000 can be performed by a control unit (e.g., the control logic 412) of a memory device (e.g., the memory device 104 or the memory device 300). The memory device can include a memory cell array (e.g., the memory cell array 301) including memory cells, and a peripheral circuit (e.g., the peripheral circuit 302) coupled to the memory cell array. In some implementations, some or all of the operations in the process 1000 can be implemented based on the techniques described in connection with FIGS. 1-9. The operations shown in the process 1000 may not be exhaustive and other operations can be performed as well before, after, or between any of the illustrated operations. Further, some of the operations may be performed simultaneously, or in a different order than shown in FIG. 10.

At 1002, the memory device is powered on, e.g., by a power-on-reset (POR) circuit. At 1004, the control circuit preloads a cache memory (e.g., the SRAM 418) with default operation setting information. The default operation setting information can be, for example, the first operation setting information 504 or the second operation setting information 506. In some cases, the operation setting information is the operation setting information of QLC operation or the operation setting information of TLC operation.

At 1006, the control circuit sets a type of operation corresponding to the default operation setting information as a default type of operation. For example, if the default operation setting information is the operation setting information of QLC operation, the control circuit sets QLC as a default type of operation. If the default operation setting information is the operation setting information of TLC operation, the control circuit sets TLC as a default type of operation.

At 1008, the control circuit receives an operation command corresponding to a current type of operation. For example, if the operation command is a QLC operation command, the current type of operation is QLC operation. If the operation command is a TLC operation command, the current type of operation is TLC operation. In some examples, the control circuit receives the operation command from a memory controller (e.g., the memory controller 106). In some examples, a block includes a plurality of pages, and all pages in the block are performed the same type of operations. In some cases, each page is operated in response to a respective operation command corresponding to the same type of operation. Therefore, more than one operation commands may be received to operate one block.

At 1010, the control circuit records the current type of operation. In some cases, the control circuit records the current type of operation in a register (e.g., the register 414). In some cases, the control circuit also records a previous type of operation in a register. The previous type of operation can be, for example, the type of operation(s) performed on a previous block that is immediately before the current block to be operated based on the operation command.

At 1012, the control circuit determines whether the current type of operation is the same as the previous type of operation. In some cases, the control circuit obtains the current type of operation and/or the previous type of operation from one or more registers, and compares whether they are the same. If the current type of operation is different from the previous type of operation, the process 1000 proceeds to 1014. If the current type of operation is the same as the previous type of operation, the process 1000 proceeds to 1016.

At 1014, the control circuit obtains current operation setting information for the current type of operation from the memory cell array. In some cases, the memory cell array includes a configure block (e.g., the configure block 502, 510, or 512). The control circuit can obtain the current operation setting information from the configure block, and replace at least a part of the previous operation setting information in the cache memory with the current operation setting information.

As an example, assume that the previous type of operations performed on the previous block is QLC and that the current type of operations performed on the current block is TLC. Accordingly, the previous operation setting information stored in the cache memory is operation setting information of QLC operation, whereas the current operation setting information is operation setting information of TLC operation. Given that TLC operations are to be performed on the current block (i.e., the current type of operation is different from the previous type of operation), the control circuit needs to replace the previous QLC operation setting information in the cache memory with the current TLC operation setting information.

In some examples, the previous operation setting information and the current operation setting information are stored in different areas of one configure block (e.g., as illustrated in FIG. 5A). In some examples, the previous operation setting information and the current operation setting information are stored in different configure blocks (e.g., as illustrated in FIG. 5B).

At 1016, the control circuit performs an operation corresponding to the operation command on the memory cell array. If the current type of operation is different from the previous type of operation, the control circuit performs an operation corresponding to the operation command on the memory cell array according to the current type of operation and the current operation setting information.

If the current type of operation is the same as the previous type of operation, the control circuit performs an operation corresponding to the operation command on the memory cell array according to the previous operation setting information. If the current type of operation is the same as the previous type of operation, the cache memory already stores the right type of operation setting information, and therefore the control circuit does not need to reload the cache memory with other operation setting information.

In some cases, the operation is a write operation, such as programming a page or a block of the memory cell array. In some cases, the operation is a read operation, such as reading data from the memory cell array.

In some examples, the control circuit receives a plurality of operation commands for operating a block, where each operation command is used to perform an operation on a page. Accordingly, the control circuit can perform, on a block, a plurality of operations corresponding to the plurality of the received operation commands. In some cases, the plurality of operations for the same block are the same type of operations.

At 1018, the control circuit sets the current type of operation in the register as a new previous type of operation. Therefore, the current type of operation in the register becomes the new previous type of operation. After the control circuit receives another operation command corresponding to a type of operation at 1008, the control circuit can determine whether the type of operation of the operation command is the same as the new previous type of operation stored in the register.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,. +−.10%, . +−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A memory device comprising:
a memory cell array comprising memory cells; and
a peripheral circuit coupled to the memory cell array and configured to:
in response to receiving a first operation command, perform a first operation corresponding to a first type of operation on the memory cell array according to first operation setting information;
and in response to receiving a second operation command, obtain second operation setting information from the memory cell array and perform a second operation corresponding to a second type of operation on the memory cell array according to the second operation setting information, wherein the second type of operation is different from the first type of operation.

2. The memory device of claim 1, wherein the peripheral circuit comprises a cache memory configured to store one of the first operation setting information or the second operation setting information.

3. The memory device of claim 2, wherein a memory area occupied by the first operation setting information has a first address range in the cache memory, a memory area occupied by the second operation setting information has a second address range in the cache memory, and the first address range and the second address range share at least one common address.

4. The memory device of claim 2, wherein the cache memory is configured to be preloaded with the first operation setting information, and wherein the cache memory is configured to store the second operation setting information obtained from the memory cell array.

5. The memory device of claim 1, wherein each of the first operation and the second operation comprises a write operation.

6. The memory device of claim 1, wherein the peripheral circuit is configured to:
operate a first memory cell according to the first type of operation, the first memory cell is configured to store a first number of bits; and
operate a second memory cell according to the second type of operation, the second memory cell is configured to store a second number of bits, and
wherein the first number of bits is different from the second number of bits.

7. The memory device of claim 6, wherein the first type of operation is quad-level cell (QLC) operation, and wherein the second type of operation is triple-level cell (TLC) operation.

8. The memory device of claim 1, wherein the peripheral circuit is configured to:
perform the first operation by applying a first voltage to a first selected word line; and
perform the second operation by applying a second voltage to a second selected word line,
wherein the first voltage and the second voltage are different in at least one of amplitude or pulse width.

9. The memory device of claim 1, wherein the memory cell array comprises a configure block, and wherein the first operation setting information and the second operation setting information are stored in different areas of the configure block, and
wherein the peripheral circuit is configured to obtain the second operation setting information from the configure block in the memory cell array.

10. The memory device of claim 1, wherein the peripheral circuit is configured to:
perform first operations corresponding to the first type of operation on memory cells in a same block; and
perform second operations corresponding to the second type of operation on memory cells in another same block.

11. The memory device of claim 1, wherein each of the second operation setting information and the first operation setting information respectively comprises at least one of:
voltage control information;
timing control information; or
process control information.

12. A memory device comprising:
a memory cell array comprising memory cells; and
a peripheral circuit coupled to the memory cell array and configured to:
receive an operation command corresponding to a current type of operation;
determine whether the current type of operation is same as a previous type of operation; and
if the current type of operation is different from the previous type of operation, obtain current operation setting information for the current type of operation from the memory cell array and perform a first operation corresponding to the operation command on the memory cell array according to the current type of operation and the current operation setting information.

13. The memory device of claim 12, wherein the peripheral circuit is configured to:
if the current type of operation is same as the previous type of operation, perform a second operation corresponding to the operation command on the memory cell array according to the previous type of operation and previous operation setting information for the previous type of operation.

14. The memory device of claim 12, wherein the peripheral circuit comprises a cache memory, and wherein the peripheral circuit is configured to:
preload the cache memory with default operation setting information; and
set a type of operation corresponding to the default operation setting information as a default type of operation.

15. The memory device of claim 14, wherein the default type of operation is quad-level cell (QLC) operation or triple-level cell (TLC) operation.

16. The memory device of claim 14, wherein the memory cell array comprises a configure block, and wherein obtaining the current operation setting information from the memory cell array comprises:
obtaining the current operation setting information from the configure block; and
replacing previous operation setting information in the cache memory with the current operation setting information.

17. The memory device of claim 16, wherein the previous operation setting information and the current operation setting information are stored in different areas of the configure block at a time point.

18. The memory device of claim 12, wherein the peripheral circuit comprises a register, and wherein the peripheral circuit is configured to:
store the previous type of operation in the register, wherein determining whether the current type of operation is same as the previous type of operation comprises comparing the current type of operation with the previous type of operation stored in the register.

19. The memory device of claim 18, wherein the peripheral circuit is configured to:
after performing the first operation, set the current type of operation in the register as a new previous type of operation.

20. A method comprising:
receiving, by a peripheral circuit of a memory device, an operation command corresponding to a current type of operation, wherein the memory device comprises a memory cell array coupled to the peripheral circuit;
determining, by the peripheral circuit, whether the current type of operation is same as a previous type of operation; and
if the current type of operation is different from the previous type of operation, obtaining current operation setting information for the current type of operation from the memory cell array and performing a first operation corresponding to the operation command on the memory cell array according to the current type of operation and the current operation setting information.
